(19) United States
(12) Patent Application Publication
(10) Pub. No.: US 2010/0117244 A1
(43) Pub. Date: May 13, 2010

(54) Semiconductor device and manufacturing method therefor

(75) Inventors: Yuichi Miyagawa, Kanagawa (JP); Takehiko Maeda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,041

(22) Filed: Nov. 5, 2009

(30) Foreign Application Priority Data
Nov. 13, 2008 (JP) 291461/2008

(51) Int. Cl. H01L 23/48; H01L 21/00

(52) U.S. Cl. 257/778; 438/108; 257/E21.001

(57) ABSTRACT

The present invention can avoid spaces not filled with resin by using simplified procedures and configuration even when multiple semiconductor chips are stacked, creating an overhanging portion. A semiconductor device 100 includes a substrate 102; a first semiconductor chip 110 mounted on the substrate 102; a second semiconductor chip 120 stacked over the first semiconductor chip 110, being separated from the first semiconductor chip 110, and provided with a portion overhanging from the first semiconductor chip 110; and an insulating resin 132 which fills a space between the first semiconductor chip 110 and the second semiconductor chip 120 as well as a space between the overhanging portion of the second semiconductor 120 chip and the substrate 102.

### BACKGROUND OF THE INVENTION

1. Field of the Invention

The present invention relates to a semiconductor device and manufacturing method therefor.

2. Description of the Related Art

When multiple semiconductor chips are mounted on a substrate such as a wiring board, to stack an equal-size semiconductor device on a semiconductor chip, a spacer (pad) smaller in size than a lower-tier semiconductor chip is installed on the lower-tier semiconductor chip before an upper-tier semiconductor chip is installed on the lower-tier semiconductor chip. This is done to prevent contact between wires of the lower-tier semiconductor chip and the upper-tier semiconductor chip. However there is a problem in that the spacer can create an overhang structure and that voids or spaces not filled with the sealing resin are produced under the overhang structure depending on filler size in a sealing resin.

Japanese Patent Laid-Open No. 2006-128169 describes a semiconductor device configured not to use a spacer. The document describes a configuration in which two types of adhesive layers are formed on the underside of a second semiconductor chip stacked on a first semiconductor chip mounted on a substrate, with wires of the first semiconductor chip entering the adhesive layers.

However, the configuration described in Japanese Patent Laid-Open No. 2006-128169 has a problem in that if the upper-tier semiconductor chip is larger in size than the lower-tier semiconductor chip, an overhang structure is created, still producing voids or spaces not filled with the sealing resin under the overhang structure. Also, when the upper-tier semiconductor chip is larger in size than the lower-tier semiconductor device, no support is provided during bonding of the upper-tier semiconductor chip, resulting in insufficient bonding strength, which may disable bonding.

Japanese Patent Laid-Open No. 2000-277559 describes a configuration in which a first pellet (device) and a second pellet are stacked on a substrate, the second pellet in the upper tier being placed in such a way as not to overlap a bonding pad of the first pellet in the lower tier, and a space between that portion (overhang structure) of the second pellet which projects from the first pellet and the substrate is filled with an insulating material. This configuration allegedly allows the pellet in the upper tier to be fastened sufficiently.

However, the technique described in Japanese Patent Laid-Open No. 2000-277559 uses a special arrangement to prevent the second pellet from overlapping the bonding pad of the first pellet in the lower tier, and consequently there are limits on geometries and arrangements of the semiconductor chips. The technique requires an additional step of filling insulating material after the second pellet is stacked on the first pellet, resulting in an increase in the number of steps. Thus, there is room for improvement.

### SUMMARY

The present invention provides a semiconductor device comprising: a substrate; a first semiconductor chip mounted on the substrate; a second semiconductor chip stacked over the first semiconductor chip, being separated from the first semiconductor chip, and provided with a portion overhanging from the first semiconductor chip; and an insulating resin which fills a space between the first semiconductor chip and the second semiconductor chip as well as a space between the overhanging portion of the second semiconductor chip and the substrate.

The present invention provides a manufacturing method for a semiconductor device, comprising a step of stacking a second semiconductor chip over a first semiconductor chip mounted on a substrate, wherein the step of stacking further comprises the steps of: placing a layer of an insulating resin equal in size to the second semiconductor chip, and the second semiconductor chip in this order on the first semiconductor chip so that the second semiconductor chip will be provided with a portion overhanging from the first semiconductor chip in a planar view; and pressing the second semiconductor chip toward the first semiconductor chip and thereby filling the insulating resin into a space between the first semiconductor chip and the second semiconductor chip as well as a space between the overhanging portion of the second semiconductor chip and the substrate.

Consequently, since the insulating resin installed between the second semiconductor chip and first semiconductor chip is placed even under that portion of the second semiconductor chip which overhangs from the first semiconductor chip, voids or spaces not filled with sealing resin can be avoided using simplified procedures and configuration. Also, voids or spaces not filled with sealing resin can be avoided regardless of arrangement of the second semiconductor chip and first semiconductor chip.

It should be noted that any combination of the above components or an apparatus or method implemented by exchanging features between the apparatus and method according to the present invention is also regarded to be an aspect of the present invention.

The present invention can avoid spaces not filled with sealing resin by using simplified procedures and configuration even when multiple semiconductor chips are stacked, creating an overhanging portion.

### BRIEF DESCRIPTION OF THE DRAWINGS

FIG. 1 is a sectional view showing a configuration of a semiconductor device according to an embodiment of the present invention;

FIG. 2 is a plan view showing the configuration of the semiconductor device according to the embodiment of the present invention;

FIGS. 3A to 3C are sectional process diagrams showing manufacturing procedures of the semiconductor device according to the embodiment of the present invention;

FIGS. 4A and 4B are diagrams showing another example of the semiconductor device shown in FIGS. 1 to 3;

FIG. 5 is a diagram showing another exemplary plan view of the semiconductor device shown in FIG. 4B;

FIGS. 6A and 6B are diagrams showing another example of the semiconductor device shown in FIGS. 1 to 5;

FIG. 7 is a diagram showing another example of the semiconductor device shown in FIGS. 1 to 5;

FIG. 8 is a plan view showing another example of the semiconductor device shown in FIG. 7;

FIGS. 9A and 9B are sectional views showing another example of the semiconductor device shown in FIGS. 1 to 3; and

FIG. 10 is a sectional view showing another example of the semiconductor device shown in FIGS. 1 to 3.

### DETAILED DESCRIPTION OF THE PREFERRED EMBODIMENTS

An embodiment of the present invention will be described below with reference to the drawings. Incidentally, the same or corresponding components will be denoted by the same reference numerals in different drawings, and detailed description thereof will be omitted as appropriate.

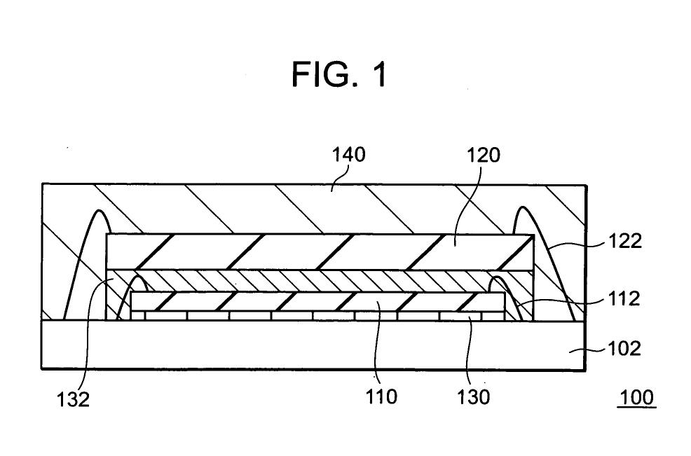

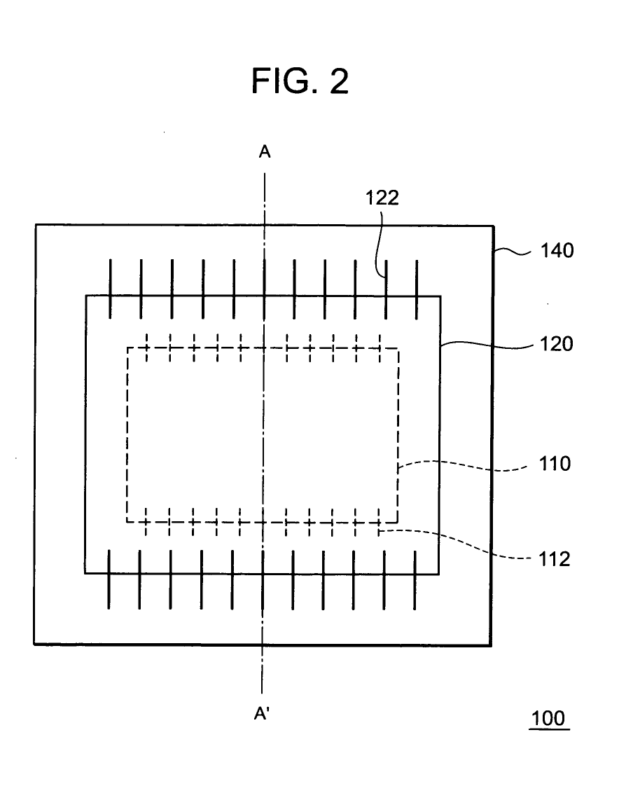

FIG. 1 is a sectional view showing a configuration of a semiconductor device 100 according to the present embodiment. FIG. 2 is a plan view schematically showing the semiconductor device 100. The sectional view in FIG. 1 is taken along A-A′ in FIG. 2. In FIG. 2, components are illustrated only by lines to make it easier to understand relative arrangement of the components.

The semiconductor device 100 includes a substrate 102, a first semiconductor chip 110 mounted on the substrate 102, and a second semiconductor chip 120 stacked on the first semiconductor chip 110. The second semiconductor chip 120 is stacked, being separated from the first semiconductor chip 110, and provided with a portion overhanging from the first semiconductor chip. The overhanging portion is that portion of the second semiconductor chip 120 under which the first semiconductor chip 110 does not exist in a planar view. The substrate 102 may be a wiring board which includes a wiring layer. According to the present embodiment, the substrate 102 may be a multilayer wiring board in which multiple wiring layers are connected.

Also, the semiconductor device 100 includes an insulating resin 132 filled in between the first semiconductor chip 110 and second semiconductor chip 120. The insulating resin 132 is also filled in between the overhanging portion of the second semiconductor chip 120 and the substrate 102. The insulating resin 132 may include, for example, an epoxy resin, a curing agent, silica, and other filling material, a flexibilizer, and the like. Also, the insulating resin 132 may be configured to have, for example, heat dissipation capability and the like. For that, the insulating resin 132 may include, for example, alumina or the like as a filling material.

The semiconductor device 100 further includes a sealing resin 140 in which the second semiconductor chip 120 and first semiconductor chip 110 are buried. The sealing resin 140 may include, for example, an epoxy resin, a curing agent, silica, and other filling material, a flexibilizer, and the like. Also, the sealing resin 140 may include, for example, carbon black to protect the first semiconductor chip 110 and second semiconductor chip 120 to be sealed. The insulating resin 132 may also include carbon black, but since the insulating resin 132 is further covered with the sealing resin 140, content of carbon black can be reduced.

The first semiconductor chip 110 includes a first bonding pad (not shown) formed on a surface which faces the second semiconductor chip 120, and bonding wires 112 (first bonding wire) which connect the first bonding pad to the substrate 102. The second semiconductor chip 120 may be configured to overhang over at least part of the bonding wires 112. Also, the insulating resin 132 buries at least part of the bonding wires 112 located below the overhanging portion of the second semiconductor chip 120.

According to the present embodiment, the insulating resin 132 is formed all over a surface (hereinafter also referred to as the rear surface) of the second semiconductor chip 120 which faces the first semiconductor chip 110. Over the entire rear surface of the second semiconductor chip 120, the insulating resin 132 is formed with a film thickness equal to or larger than at least the distance between the first semiconductor chip 110 and second semiconductor chip 120. According to the present embodiment, the second semiconductor chip 120 overhangs over all the bonding wires 112 of the first semiconductor chip 110. Also, the bonding wires 112 of the first semiconductor chip 110 are completely buried in the insulating resin 132.

In the overhanging portion, the second semiconductor chip 120 contains a second bonding pad (not shown) formed on a surface opposite from the surface facing the first semiconductor chip 110, and bonding wires 122 (second bonding wires) which connect the second bonding pad to the substrate 102.

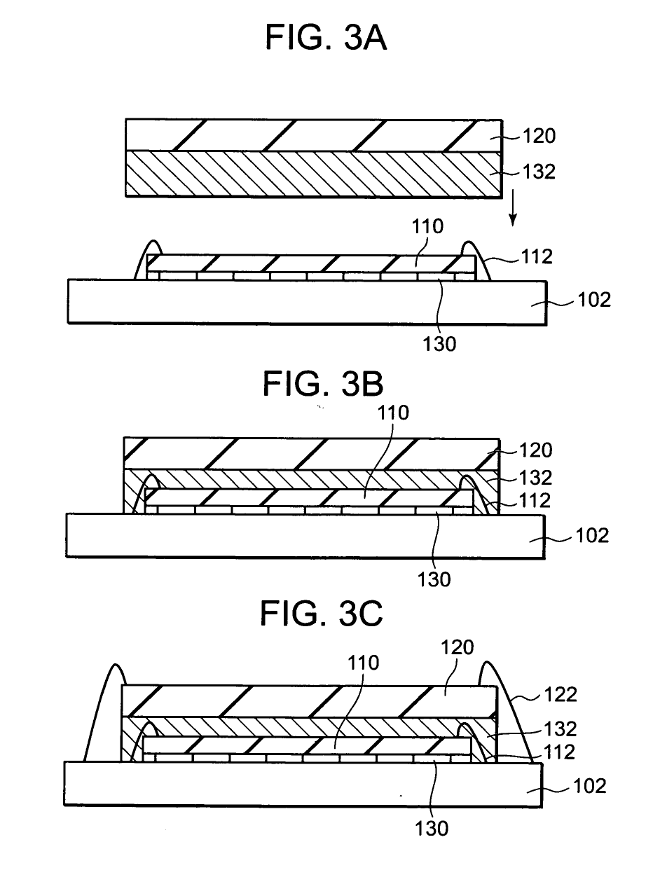

FIGS. 3A to 3C are sectional process diagrams showing manufacturing procedures of the semiconductor device 100 according to the present embodiment. The manufacturing procedures of the semiconductor device 100 will be described below with reference to FIGS. 3A to 3C.

First, the first semiconductor chip 110 is mounted on the substrate 102 via an adhesive 130 which is a mounting material. The adhesive 130 may be, for example, a conductive paste such as an Ag paste, an insulating paste such as an insulating resin, a die attach film (DAF), or the like. Next, the first bonding pad of the first semiconductor chip 110 is electrically connected to the substrate 102 via the bonding wires 112. Consequently, the first semiconductor chip 110 is mounted on the substrate 102.

Next, the second semiconductor chip 120 is stacked on the first semiconductor chip 110 mounted on the substrate 102. This step further includes a step of placing a layer of an insulating resin 132 equal in size to the second semiconductor chip 120, and the second semiconductor chip 120 in this order on the first semiconductor chip 110 so that the second semiconductor chip 120 will be provided with a portion overhanging from the first semiconductor chip 110 in a planar view; and a step of pressing the second semiconductor chip 120 toward the first semiconductor chip 110 and thereby filling the insulating resin 132 into a space between the first semiconductor chip 110 and the second semiconductor chip 120 as well as a space between the overhanging portion of the second semiconductor chip 120 and the substrate 102.

According to the present embodiment, a layer of the insulating resin 132 is pasted as a mounting material to the entire rear surface of the second semiconductor chip 120 in advance. According to the present embodiment, the layer of the insulating resin 132 may be formed as a film layer. For example, the layer of the insulating resin 132 may be a film layer which is adhesive on both sides.

Also, the layer of the insulating resin 132 has a film thickness equal to or larger than thickness of the first semiconductor chip 110 in a lower tier. Height of the first semiconductor chip 110 mounted under the second semiconductor chip 120 is, for example, on the order of 15 to 100 μm although not limited specifically. Considering height of the bonding wires 112, preferably the film thickness of the layer of the insulating resin 132 is larger than the height of the first semiconductor chip 110 plus approximately 50 μm.

In this way, the second semiconductor chip 120 with the film of the insulating resin 132 pasted on the rear surface is mounted on the substrate 102 on which the first semiconductor chip 110 is mounted and is pressed toward the first semiconductor chip 110 (FIG. 3A). The layer of the insulating resin 132 is applied, in an uncured state, to the rear surface of the second semiconductor chip 120. When mounted on the first semiconductor chip 110, the second semiconductor chip 120 may be heated. Consequently, the insulating resin 132 will soften (gelate) and have its viscosity reduced, making it possible to bury the bonding wires 112 of the first semiconductor chip 110 in the insulating resin 132 without deforming the bonding wires 112. Subsequently, the insulating resin 132 is cured. Consequently, the insulating resin 132 fills the space between the first semiconductor chip 110 and second semiconductor chip 120, creating a configuration in which the gap between the first semiconductor chip 110 and second semiconductor chip 120 is plugged by the insulating resin 132. In so doing, the insulating resin 132 formed on the rear surface of the overhanging portion of the second semiconductor chip 120 is brought into contact with the substrate 102. Consequently, the space between the overhanging portion of the second semiconductor chip 120 and the substrate 102 is also filled with the insulating resin 132. At the same time, the bonding wires 112 of the first semiconductor chip 110 are buried all together in the insulating resin 132. This results in a configuration shown in FIG. 3B.

Subsequently, the second bonding pad formed on the surface of the second semiconductor chip 120 is electrically connected with the substrate 102 via the bonding wires 122. Consequently, the second semiconductor chip 120 is mounted on the substrate 102 (FIG. 3C).

Next, the second semiconductor chip 120, the first semiconductor chip 110, and the bonding wires 122 of the second semiconductor chip 120 are sealed by the sealing resin 140. This results in the semiconductor device 100 of the configuration shown in FIG. 1.

When a film layer which is adhesive on both sides is used as the insulating resin 132, instead of being pasted to the rear surface of the second semiconductor chip 120, the insulating resin 132 may be pasted to the first semiconductor chip 110 before the second semiconductor chip 120 is mounted. In this case, the insulating resin 132 is configured to be of equal size or larger than the second semiconductor chip 120 in a planar view and placed on that location of the first semiconductor chip 110 on which the second semiconductor chip 120 will be mounted. Next, the second semiconductor chip 120 is placed on the insulating resin 132 in such a way as to overlap the insulating resin 132 and is pressed toward the first semiconductor chip 110. This also results in the configuration shown in FIG. 3B.

Advantages of the semiconductor device 100 according to the present embodiment will be described next.

Since the insulating resin 132 filled in between the first semiconductor chip 110 and second semiconductor chip 120 also fills the space under the overhanging portion of the second semiconductor chip 120, the present embodiment can avoid voids or spaces not filled with sealing resin under the overhanging portion using simplified procedures. Also, the present embodiment can avoid voids or spaces not filled with sealing resin regardless of arrangement of the second semiconductor chip 120 and first semiconductor chip 110.

Furthermore, since the space under the overhanging portion of the second semiconductor chip 120 is filled with the insulating resin 132, which provides a support during bonding of the second semiconductor chip 120, the bonding wires 122 can be bonded properly. Furthermore, since the bonding wires 112 of the first semiconductor chip 110 are buried in the insulating resin 132, wire sweep caused by the sealing resin 140 and effects of a filler or the like contained in the sealing resin 140 on the wires can be eliminated.

According to the present embodiment, since the bonding wires 112 are buried in a single type of insulating resin 132, it is possible to eliminate the possibility of fracture of the bonding wires 112 due to differences in the linear expansion of material surrounding the bonding wires 112. Furthermore, the present embodiment eliminates spacers, and thereby enables package size reduction.

### Other Examples

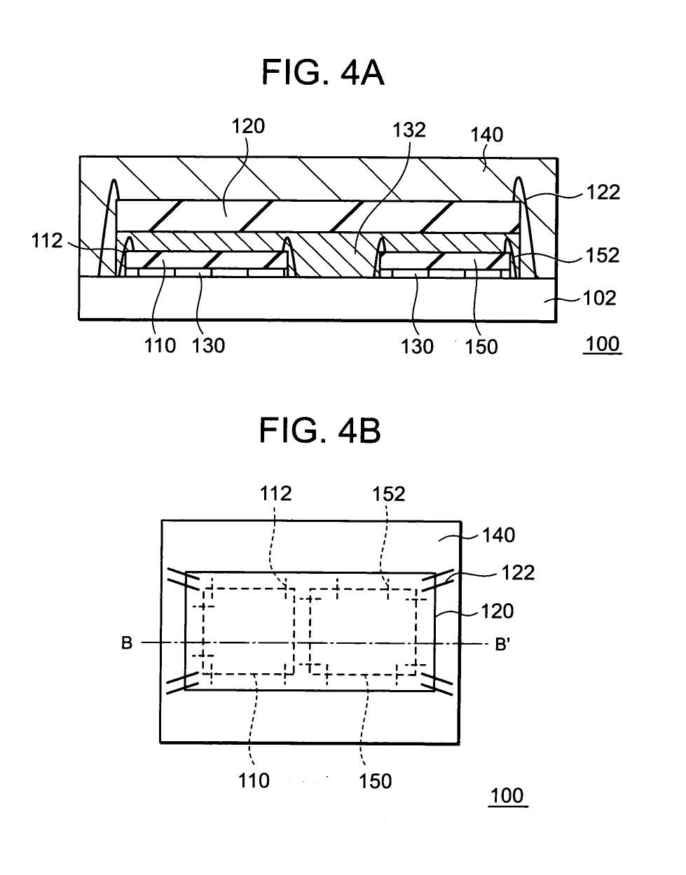

FIGS. 4A and 4B are diagrams showing another example of the semiconductor device 100 shown in FIGS. 1 to 3. FIG. 4A is a sectional view and FIG. 4B is a plan view. The sectional view in FIG. 4A is taken along B-B′ in FIG. 4B. In FIG. 4B, components are illustrated only by lines to make it easier to understand relative arrangement of the components.

In the present example, a third semiconductor chip 150 may be mounted in the same layer as the first semiconductor chip 110 on the substrate 102, being placed side by side with the first semiconductor chip 110. While covering the first semiconductor chip 110 and third semiconductor chip 150, the second semiconductor chip 120 can have a portion overhanging from the first semiconductor chip 110 and third semiconductor chip 150.

The third semiconductor chip 150 includes a bonding pad (not shown) formed on a surface which faces the second semiconductor chip 120, and bonding wires 152 which connect the bonding pad to the substrate 102. The bonding wires 152 can also be completely buried in the insulating resin 132. Also, under the overhanging portion of the second semiconductor chip 120, i.e., under that part of the second semiconductor chip 120 where the first semiconductor chip 110 and third semiconductor chip 150 do not exist in a planar view, the space between the second semiconductor chip 120 and substrate 102 may be filled with the insulating resin 132, with the insulating resin 132 being placed in contact with the substrate 102.

In the present example, when the second semiconductor chip 120 is mounted on the first semiconductor chip 110, the film thickness of the layer of the insulating resin 132 may be larger than the height of the higher of the first semiconductor chip 110 and third semiconductor chip 150 plus approximately 50 μm. This configuration also provides the same advantages as the semiconductor device 100 shown in FIGS. 1 to 3.

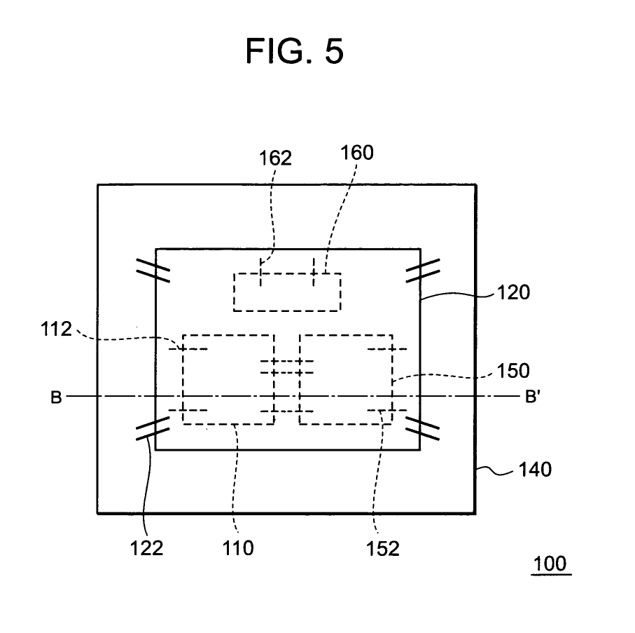

FIG. 5 is a diagram showing another exemplary plan view of the semiconductor device 100 shown in FIG. 4B. FIG. 4A also shows a sectional view taken along B-B′ in FIG. 5. In FIG. 5 again, components are illustrated only by lines to make it easier to understand relative arrangement of the components.

As shown in FIG. 5, still another semiconductor chip 160 may be mounted in the same layer as the first semiconductor chip 110 and third semiconductor chip 150 on the substrate 102, being placed beside the first semiconductor chip 110 and third semiconductor chip 150. While covering the first semiconductor chip 110, third semiconductor chip 150, and semiconductor chip 160, the second semiconductor chip 120 can have a portion overhanging from the first semiconductor chip 110, third semiconductor chip 150, and semiconductor chip 160.

The semiconductor chip 160 includes a bonding pad (not shown) formed on a surface which faces the second semiconductor chip 120, and bonding wires 162 which connect the bonding pad to the substrate 102. The bonding wires 162 can also be completely buried in the insulating resin 132. Also, under the overhanging portion of the second semiconductor chip 120, i.e., under that part of the second semiconductor chip 120 where the first semiconductor chip 110, third semiconductor chip 150, and semiconductor chip 160 do not exist in a planar view, the space between the second semiconductor chip 120 and substrate 102 may be filled with the insulating resin 132, with the insulating resin 132 being placed in contact with the substrate 102.

In the present example, when the second semiconductor chip 120 is mounted on the first semiconductor chip 110, the film thickness of the layer of the insulating resin 132 may be larger than the height of the highest of the first semiconductor chip 110, third semiconductor chip 150, and semiconductor chip 160 plus approximately 50 μm. This configuration also provides the same advantages as the semiconductor device 100 shown in FIGS. 1 to 3.

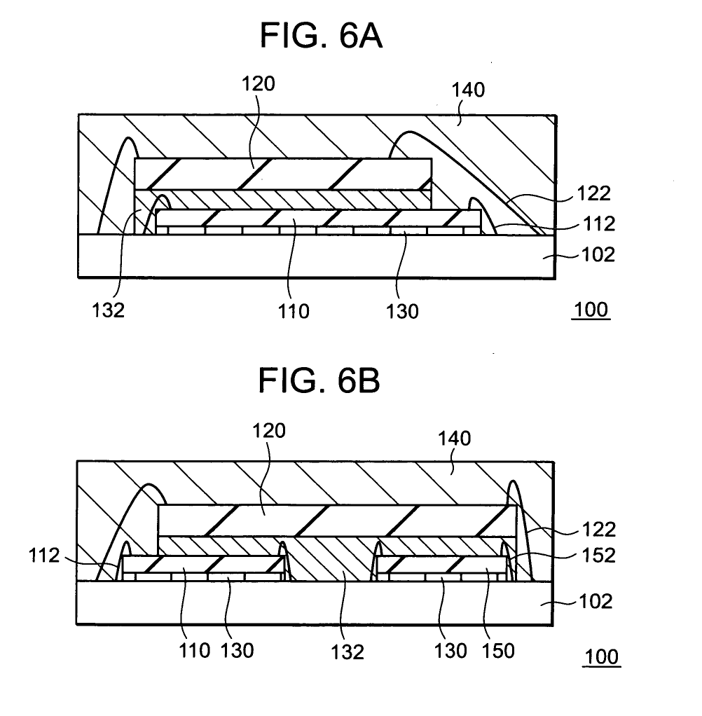

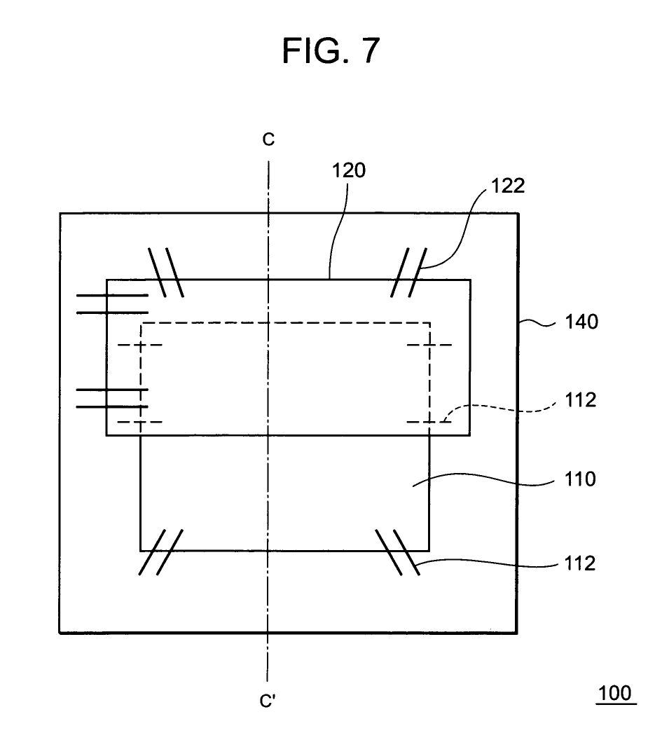

FIGS. 6A, 6B, and 7 are diagrams showing still another example of the semiconductor device 100 shown in FIGS. 1 to 5. FIGS. 6A and 6B are sectional views and FIG. 7 is a plan view. The sectional view in FIG. 6A is taken along C-C′ in FIG. 7. In FIG. 7 again, components are illustrated only by lines to make it easier to understand relative arrangement of the components. FIG. 6A shows a configuration in which the first semiconductor chip 110 alone is mounted under the second semiconductor chip 120 while FIG. 6B shows a configuration in which the first semiconductor chip 110 and third semiconductor chip 150 are mounted under the second semiconductor chip 120 as in the case of FIG. 4. The examples in FIGS. 6A and 6B differ from the examples in FIGS. 1 to 5 in that the first semiconductor chip 110 in the lower tier is not completely covered by the second semiconductor chip 120.

Again, the second semiconductor chip 120 can have a portion overhanging from the first semiconductor chip 110 and third semiconductor chip 150. The second semiconductor chip 120 may be configured to overhang over at least part of the bonding wires 112 and bonding wires 152 of the semiconductor chips in the lower tier. Also, the insulating resin 132 buries the bonding wires 112 located below the overhanging portion of the second semiconductor chip 120.

Also, under the overhanging portion of the second semiconductor chip 120, i.e., under that part of the second semiconductor chip 120 where the first semiconductor chip 110 and third semiconductor chip 150 do not exist in a planar view, the space between the second semiconductor chip 120 and substrate 102 may be filled with the insulating resin 132, with the insulating resin 132 being placed in contact with the substrate 102. This configuration also provides the same advantages as the semiconductor device 100 shown in FIGS. 1 to 5.

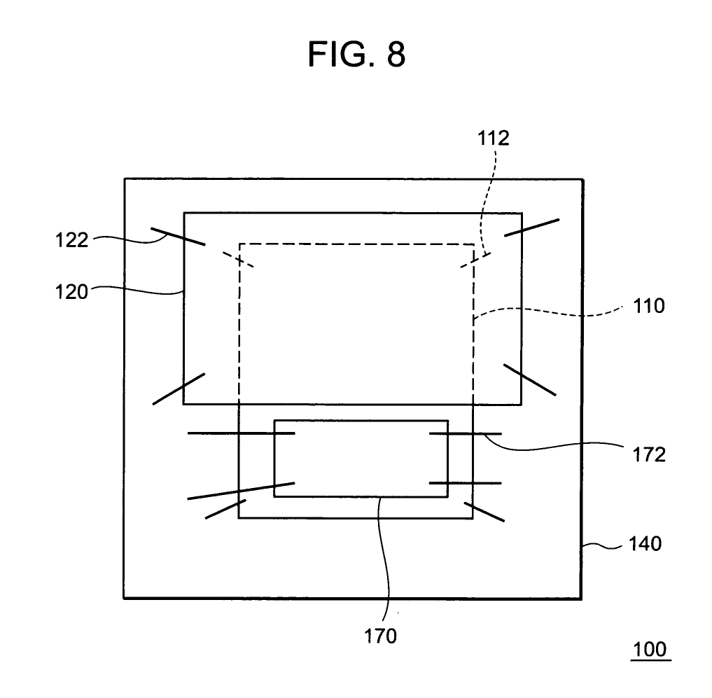

FIG. 8 is a plan view showing another example of the semiconductor device 100 shown in FIG. 7. In FIG. 8 again, components are illustrated only by lines to make it easier to understand relative arrangement of the components. The example in FIG. 8 differs from the example in FIG. 7 in that a semiconductor chip 170 is further mounted on the first semiconductor chip 110 in the lower tier.

The semiconductor chip 170 contains a bonding pad (not shown) formed on a surface opposite from the surface facing the first semiconductor chip 110, and bonding wires 172 which connect the bonding pad to the substrate 102. In the present example, the semiconductor chip 170 may be mounted on the first semiconductor chip 110 by using the same insulating resin 132 as the one attached to the second semiconductor chip 120 or the similar adhesive as the adhesive 130. This configuration also provides the same advantages as the semiconductor device 100 shown in FIGS. 1 to 3.

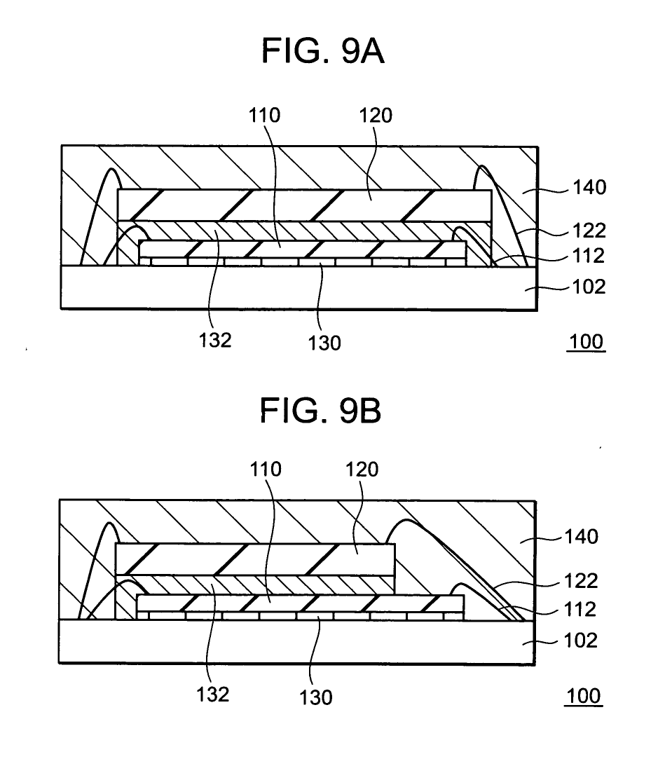

FIGS. 9A and 9B are sectional views showing another example of the semiconductor device 100 shown in FIGS. 1 to 3. The example in FIGS. 9A and 9B differs from the examples in FIGS. 1 to 3 in that the bonding wires 112 of the first semiconductor chip 110 in the lower tier are not completely buried in the insulating resin 132.

That is, in this example, the second semiconductor chip 120 may be configured to overhang over at least part of the bonding wires 112. Also, the insulating resin 132 buries part of the bonding wires 112 located below the overhanging portion of the second semiconductor chip 120, i.e., the insulating resin 132 buries connections of the bonding wires 112 with the bonding pad on the surface of the first semiconductor chip 110. The rest of the first semiconductor chip 110 is buried in the sealing resin 140.

This configuration also can avoid voids or spaces not filled with resin by using simplified procedures. Also, since the insulating resin 132 provides a support during bonding of the second semiconductor chip 120, the bonding wires 122 can be bonded properly. Furthermore, since the connections with the bonding pad on the surface of the first semiconductor chip 110 are buried in the insulating resin 132, wire sweep and the like caused by the sealing resin 140 can be avoided.

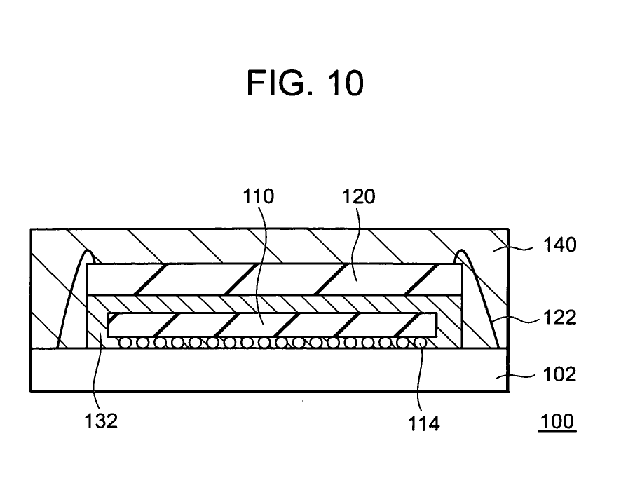

FIG. 10 is a sectional view showing another example of the semiconductor device 100 shown in FIGS. 1 to 3. The configuration shown in FIG. 10 differs from the configurations shown in FIGS. 1 to 3 in that the semiconductor device 100 are connected to the substrate 102 via bumps 114 for flip-chip connection instead of using the bonding wires 112. This configuration also can avoid voids or spaces not filled with resin under the overhanging portion using simplified procedures. Also, since the insulating resin 132 provides a support during bonding of the second semiconductor chip 120, the bonding wires 122 can be bonded properly.

An embodiment of the present invention has been described above with reference to the drawings, but only by way of example, and various other configurations may be used in addition to those described above.

In the above embodiment, a film layer of the insulating resin 132 has been described by way of example, but the insulating resin 132 may be a liquid resin. For example, the semiconductor device 100 may be manufactured by applying a generous amount of liquid resin to the surface of the first semiconductor chip 110 and placing the second semiconductor chip 120 on the first semiconductor chip 110. Also, if shape of the liquid resin can be maintained to some extent, the semiconductor device 100 may be manufactured by applying the liquid resin to the rear surface of the second semiconductor chip 120 and placing the second semiconductor chip 120 on the first semiconductor chip 110.

What is claimed is:

1. A semiconductor device comprising:
a substrate;
a first semiconductor chip mounted on the substrate;
a second semiconductor chip stacked over the first semiconductor chip, being separated from the first semiconductor chip, and provided with a portion overhanging from the first semiconductor chip; and
an insulating resin which fills a space between the first semiconductor chip and the second semiconductor chip as well as a space between the overhanging portion of the second semiconductor chip and the substrate.

2. The semiconductor device according to claim 1, wherein the insulating resin is formed all over a surface of the second semiconductor chip which faces the first semiconductor chip.

3. The semiconductor device according to claim 1, wherein:
the first semiconductor chip includes a first bonding pad formed on a surface which faces the second semiconductor chip, and a first bonding wire which connects the first bonding pad to the substrate;
the second semiconductor chip overhangs over at least part of the first bonding wire; and
the insulating resin fills the at least part of the first bonding wire located below the overhanging portion of the second semiconductor chip.

4. The semiconductor device according to claim 1, wherein the second semiconductor chip includes, in the overhanging portion, a second bonding pad formed on a surface opposite from the surface facing the first semiconductor chip, and a second bonding wire which connects the second bonding pad to the substrate;

5. A manufacturing method for a semiconductor device, comprising:
preparing a first semiconductor chip mounted on a substrate,
placing a layer of an insulating resin, and a second semiconductor chip equal in size to the layer of the insulating resin in this order on the first semiconductor chip so that the second semiconductor chip is provided a overhanging portion from the first semiconductor chip; and
pressing the second semiconductor chip toward the first semiconductor chip and thereby filling the insulating resin into a space between the first semiconductor chip and the second semiconductor chip as well as a space between the overhanging portion of the second semiconductor chip and the substrate.

6. The manufacturing method for a semiconductor device according to claim 5, wherein placing the layer of the insulating resin and the second semiconductor chip in this order, the second semiconductor chip is placed on the first semiconductor chip with the layer of the insulating resin pasted all over a surface of the second semiconductor chip which faces the first semiconductor chip.

7. The manufacturing method for a semiconductor device according to claim 5, wherein the layer of the insulating resin has a film thickness equal to or larger than height of the first semiconductor chip.

8. The manufacturing method for a semiconductor device according to claim 5, wherein the layer of the insulating resin is formed as a film layer.
